(19) United States
(12) Patent Application Publication
(10) Pub. No.: US 2014/0209242 A1
(43) Pub. Date: Jul. 31, 2014

(54) SUBSTRATE PROCESSING CHAMBER COMPONENTS INCORPORATING ANISOTROPIC MATERIALS

(71) Applicant: APPLIED MATERIALS, INC., Santa Clara, CA (US)

(72) Inventors: JENNIFER Y. SUN, Mountain View, CA (US); BIRAJA PRASAD KANUNGO, San Jose, CA (US)

(73) Assignee: APPLIED MATERIALS, INC., Santa Clara, CA (US)

(21) Appl. No.: 13/838,510

(22) Filed: Mar. 15, 2013

Related U.S. Application Data
(60) Provisional application No. 61/756,829, filed on Jan. 25, 2013.

(51) Int. Cl. H01L 21/02; H01L 21/67

(52) U.S. Cl. CPC H01L 21/02; H01L 21/67098
USPC 156/345.34; 156/345.37; 156/345.53; 165/133

(57) ABSTRACT

Substrate processing chamber components for use in substrate processing chambers are provided herein. In some embodiments, a substrate processing chamber component may include a body having a first surface, one or more heat exchangers disposed within the body below the first surface, and one or more anisotropic layers, wherein a separate anisotropic layer is disposed between each of the one or more heat exchangers and the first surface.

### CROSS-REFERENCE TO RELATED APPLICATIONS

This application claims benefit of U.S. provisional patent application Ser. No. 61/756,829, filed Jan. 25, 2013, which is herein incorporated by reference in its entirety.

### FIELD

Embodiments of the present invention generally relate to semiconductor substrate processing systems. More specifically, the present invention relates to substrate process chamber components.

### BACKGROUND

The temperature uniformity and tuning of a substrate in a semiconductor processing system depends on the temperature uniformity and tuning of various chamber components, such as the electrostatic chuck, the showerhead, the chamber liner, and the like. Chamber components may be heated using a heater embedded within the chamber component, which can create non-uniform heating zones across the surface of the chamber component. Such non-uniform heating zones can create non-uniform processing conditions, for example, from the center to the edge of a substrate by up to about 5 to about 10 degrees Celsius. The resulting unevenness in, for example, deposition or etching processes performed on the substrate can negatively impact semiconductor performance.

Accordingly, the inventors have provided improved chamber components for use in semiconductor substrate processing systems.

### SUMMARY

Substrate processing chamber components for use in substrate processing chambers are provided herein. In some embodiments, a substrate processing chamber component may include a body having a first surface, one or more heat exchangers disposed within the body below the first surface, and one or more anisotropic layers, wherein a separate anisotropic layer is disposed between each of the one or more heat exchangers and the first surface.

In some embodiments, a substrate processing chamber may include a processing volume defined by a top chamber wall, a bottom chamber wall and a plurality of side walls; and a substrate processing chamber component disposed within the chamber volume, wherein the substrate processing chamber component includes a body having a first surface, one or more heat exchangers disposed within the body below the first surface, and one or more anisotropic layers, wherein a separate anisotropic layer is disposed between each of the one or more heat exchangers and the first surface.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIGS. 1A-1B respectively depict side and top cross-sectional views of a chamber component in accordance with some embodiments of the present invention.

FIG. 2 depicts a semiconductor substrate process chamber having chamber components in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention provide improved substrate process chamber components. Embodiments of the improved chamber components advantageously allow for improved thermal uniformity across the surface of the chamber component, which may lead to more uniform substrate processing. Embodiments of the improved processing chamber components may also advantageously provide improved control of the thermal profile across different portions of the surface of the processing chamber component.

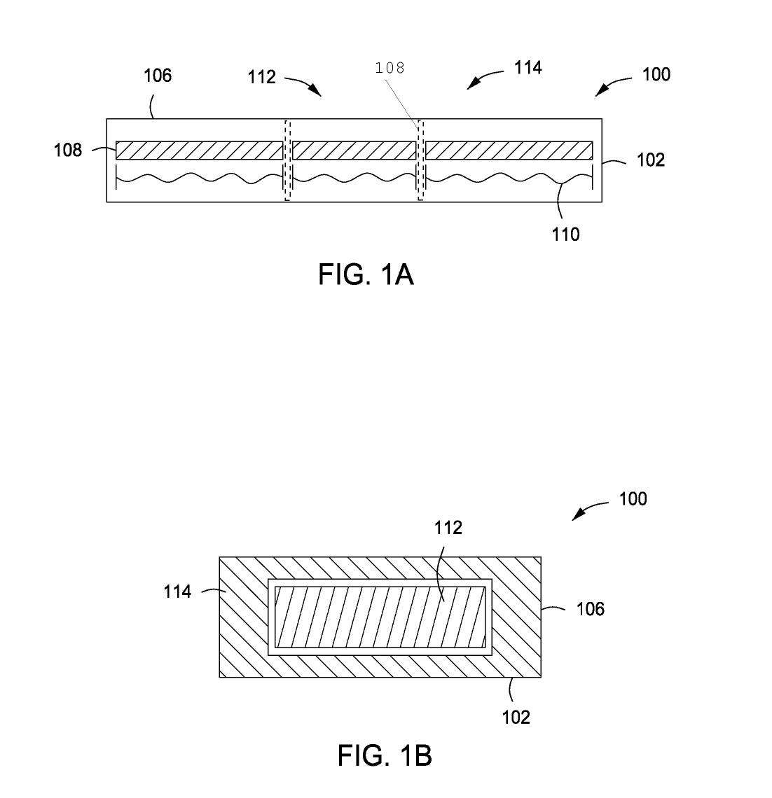

FIGS. 1A-1B depict an example of a process chamber component 100, in accordance with the some embodiments of the present invention. The process chamber component 100 may be any process chamber component 100 that is heated or cooled during processing for example, such as an electrostatic chuck, a process chamber liner, a showerhead, or the like. The process chamber component 100 comprises a body 102 having a first surface 106. In some embodiments, the body 102 may be a metal, a metal alloy, or a dielectric material depending on the specific chamber component. For example, in some embodiments where the chamber component 100 is a liner or a showerhead the body may be metal, such as aluminum, anodized aluminum, titanium, copper, stainless steel, a metal alloy or the like. In some embodiments, for example where the chamber component is a electrostatic chuck, the body may be a dielectric material such as a ceramic bonded to a conductive metal or alloy, or the like.

In some embodiments, a heat exchanger 110 is embedded in the body 102 below the first surface 106. In some embodiments, the heat exchanger 110 is a heater. The heater may be any type of heater used to heat a process chamber component. For example, in some embodiments, the heater may comprise one or more electrically resistive elements coupled to a power source. In some embodiments, multiple electrically restive elements may be utilized to provide separate heating zones within the process chamber component 100.

In embodiments where the process chamber component 100 comprises multiple zones or multiple heaters, power to all of the multiple zones or multiple heaters may be applied simultaneously. In such embodiments, the power may be applied at the same rate, or in some embodiments, at a different rate for each one of the multiple zones or multiple heaters. For example, as depicted in FIG. 1, the body 102 comprises two heaters creating two heating zones, a center or inner heating zone 112 and an edge or outer heating zone 114 wherein the temperature of each zone is independently controllable. Although shown having two zones, the body 102 may have any amount of zones, for example such as one zone, or three or more zones. In some embodiments, the heat exchanger 110 may be one or more coolant channels within the body 100 carrying a cooling fluid. Similar to the use of multiple electrically restive elements described above, in some embodiments, multiple coolant channels may be utilized to provide separate cooling zones within the process chamber component 100.

In some embodiments, an anisotropic material 108 is disposed in the body 102 between the heat exchanger 110 and the first surface 106. An anisotropic material 108 is a material that advantageously has an in-plane thermal conductivity (conductivity in the basal plane) much greater than its transverse thermal conductivity allowing for temperature uniformity in the direction of the plane. Thermal pyrolitic graphite (TPG) is an example of an anisotropic material 108 having an in-plane thermal conductivity of about 1,500 W/m-K and a transverse thermal conductivity of about 10 W/m-K. Other examples of suitable anisotropic materials include pyrolitic boron nitride or the like. In some embodiments, the anisotropic material 108 may be cut into a variety of shapes including rectangular, square, or circular. In some embodiments, the anisotropic material 108 can also be used to improve the electrical uniformity of the process chamber component 100 by providing an in-plane electrical conductivity (conductivity in the basal plane) greater than its transverse electrical conductivity allowing for electrical uniformity in the direction of the plane.

In some embodiments, an insulating material, for example an anisotropic material 108, may be disposed in the body 102 between the heat exchangers 110 in the inner heating zone 112 and the outer heating zone 114. The anisotropic material 108 disposed between the heat exchangers 110 is oriented in the low conductivity direction, (perpendicular to the in-plane direction) to reduce thermal or electrical conductivity between different zones. In some embodiments, the anisotropic material 108 disposed between the heat exchangers may be the same as the anisotropic material disposed between the heat exchanger 110 and the first surface 106. In some embodiments, the anisotropic material 108 disposed between the heat exchangers may be different from the anisotropic material disposed between the heat exchanger 110 and the first surface 106.

In some embodiments, the anisotropic material 108 is bonded to the body 102 by diffusion bonding, soldering, lamination or brazing. In some embodiments, for example where the anisotropic material 108 is bonded to the body 102 via lamination, an anisotropic material 108 can be selected having a coefficient of thermal expansion that is similar to the coefficient of thermal expansion of the body 102 in order to prevent de-lamination of the anisotropic material 108. For example, TPG can be used as an anisotropic material 108 for a body 102 made from materials having a similar coefficient of thermal expansion such as aluminum, aluminum silicon carbide, tungsten, or a tungsten-copper alloy.

In some embodiments, as depicted in FIG. 1, where the body 102 comprises multiple electrically restive elements, a separate anisotropic material 108 may be disposed within the body 102 between the heat exchanger 110 and the first surface 106. While each temperature zone 112, 114 may have a different temperature, the high in-plane thermal conductivity of the anisotropic material 108 advantageously allows for a uniform temperature profile across each temperature zone 112, 114. Without an anisotropic material 108, each temperature zone 112, 114 would have a temperature gradient of about 5 to about 10 degrees Celsius. In contrast, an anisotropic material 108 advantageously decreases the temperature gradient across each temperature zone from about 5 to about 10 degrees Celsius to about 1 to about 2 degrees Celsius. As discussed above, in some embodiments, where the body 102 comprises multiple electrically restive elements an anisotropic material 108 may also be disposed within the body 102 between the heat exchangers 110 in the inner heating zone 112 and the outer heating zone 114. As discussed above, the anisotropic material 108 disposed between the heat exchangers 110 is oriented in the low conductivity direction, (perpendicular to the in-plane direction). For example, in some embodiments, the temperature difference between the inner heating zone 112 and the outer heating zone 114 is about 10 to about 30 degrees Celsius. The anisotropic material 108 oriented in the low conductivity direction advantageously reduces conductivity between the different zones.

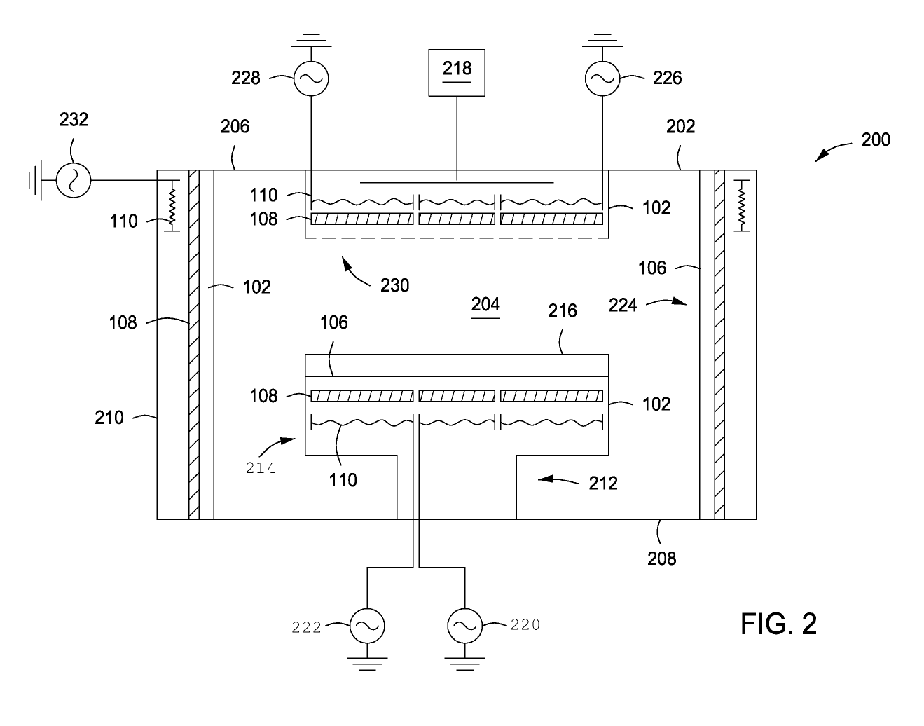

FIG. 2 is a schematic view of substrate processing chamber 200 in accordance with some embodiments of the present invention. The process chamber 200 may be any type of chamber, for example an etch chamber, such as, but not limited to, the Enabler™, Producer, MxP®, MxP+™, Super-E™, DPS II AdvantEdge™ G3, or E-MAX® chambers manufactured by Applied Materials, Inc., located in Santa Clara, Calif. Other process chambers, including those from other manufacturers, may similarly benefit from use of the methods as described herein.

The process chamber 200 generally comprises a chamber body 202 having an inner volume 204 defined by a top chamber wall 206, an opposing bottom chamber wall 208, and sidewalls 210. Various chamber components, having the characteristics described above may be disposed within the inner volume 204. For example, in some embodiments, a substrate support 212 having an electrostatic chuck 214 to retain or support a substrate 216 on the surface of the substrate support 212 is disposed within the inner volume 204.

In some embodiments, a plurality of heat exchangers 110 is embedded within the body of the electrostatic chuck 214. In some embodiments, the heat exchangers 110 are heaters as described above. In some embodiments, each heater is coupled to a separate power source 220, 222. In some embodiments, each heater may be coupled to the same power source. A separate anisotropic material 108 may be disposed within the body 102 of the electrostatic chuck 214 between each heat exchanger 110 and the first surface 106. Each heater creates a separate heating zone atop the first surface of the body 106, creating a corresponding heating zone on the substrate 216. While each temperature zone may have a different temperature, the high in-plane thermal conductivity of the anisotropic material 108 advantageously allows for a uniform temperature profile across each temperature zone.

In some embodiments, a showerhead 230 is disposed within the inner volume 204, opposite the top surface 106 of the substrate support 212. In some embodiments, the showerhead 230 may be disposed along the top chamber wall 206 or on the sidewalls 210 of the process chamber 200 or at other locations suitable for providing gases as desired to the process chamber 200. The showerhead 230 may be coupled to a gas supply 218 for providing one or more process gases into the inner volume 204 of the process chamber 200. In some embodiments, a single heat exchanger 110, coupled to a single power source, is embedded within the body 102 of the showerhead 230 and a single layer of anisotropic material 108 is disposed within the body 102 between the heat exchanger 110 and the first surface 106. In some embodiments, the heat exchangers 110 are heaters as described above. The anisotropic material 108 advantageously creates a uniform temperature profile across the first surface 106 of the showerhead 230.

In some embodiments, as depicted in FIG. 2, a plurality of heat exchangers 110 is embedded within the body 102 of the showerhead 230. In some embodiments, the heat exchangers 110 are heaters as described above. In some embodiments, each heater is coupled to a separate power source 226, 228. In some embodiments, each heater may be coupled to the same power source. A separate anisotropic material 108 may be disposed within the body 102 of the showerhead 230 between each heat exchanger 110 and the first surface 106. Each heater creates a separate heating zone atop the first surface of the body 106, creating a corresponding heating zone on the first surface 106 of the showerhead 230. While each temperature zone may have a different temperature, the high in-plane thermal conductivity of the anisotropic material 108 advantageously allows for a uniform temperature profile across each temperature zone.

In some embodiments, a chamber liner 224 may be disposed within the process chamber 200 to protect the sidewalls 210 of the process chamber 200 from damage due to processing (such as from the plasma or from sputtering or other process byproducts) as well as to reduce on-wafer defects coming from the chamber body 200. In some embodiments, the chamber liner 224 may further extend to line the top chamber wall 206 of the process chamber 102.

In some embodiments, as depicted in FIG. 2, a single heat exchanger 110, coupled to a single power source 232, is embedded within the body 102 of the chamber liner 224 and a single layer of anisotropic material 108 is disposed within the body 102 between the heat exchanger 110 and the first surface 106. The anisotropic material 108 advantageously creates a uniform temperature profile across the first surface 106 of the chamber liner 224.

In some embodiments, a plurality of heat exchangers 110 is embedded within the body 102 of the chamber liner 224. In some embodiments, the heat exchangers 110 are heaters as described above. In some embodiments, each heater is coupled to a separate power source. In some embodiments, each heater may be coupled to the same power source. A separate anisotropic material 108 may be disposed within the body 102 of the chamber liner 224 between each heat exchanger 110 and the first surface 106. Each heater creates a separate heating zone atop the first surface of the body 106, creating a corresponding heating zone on the first surface 106 of the chamber liner 224. While each temperature zone may have a different temperature, the high in-plane thermal conductivity of the anisotropic material 108 advantageously allows for a uniform temperature profile across each temperature zone.

Thus, improved semiconductor substrate processing chamber components are provided herein. The inventive apparatus advantageously allows for improved thermal uniformity and thermal tuning across the surface of the chamber component.

While the foregoing is directed to embodiments of the present invention, other and further embodiments of the invention may be devised without departing from the basic scope thereof.

1. A substrate processing chamber component, comprising:
a body having a first surface;
one or more heat exchangers disposed within the body below the first surface; and
one or more anisotropic layers, wherein a separate anisotropic layer is disposed between each of the one or more heat exchangers and the first surface.

2. The substrate processing chamber component of claim 1, wherein the substrate processing chamber component is at least one of a showerhead, an electrostatic chuck or a chamber liner.

3. The substrate processing chamber component of claim 1, wherein the one or more heat exchangers are heaters.

4. The substrate processing chamber component of claim 1, further comprising a plurality of temperature zones across the first surface of the body, wherein a temperature across each temperature zone is substantially uniform.

5. The substrate processing chamber component of claim 4, wherein a temperature gradient within each temperature zone is about 1 to about 2 degrees Celsius.

6. The substrate processing chamber component of claim 4, wherein each temperature zone is associated with a separate heat exchanger disposed within the body below each temperature zone.

7. The substrate processing chamber component of claim 1, wherein the one or more heat exchangers are cooling channels.

8. The substrate processing chamber component of claim 1, wherein each of the one or more heat exchangers and corresponding anisotropic layers are separated by an insulating material embedded within the body.

9. The substrate processing chamber component of claim 1, comprising one or more power sources coupled to each of the one or more heat exchangers.

10. The substrate processing chamber component of claim 1, wherein the anisotropic layer comprises a coefficient of thermal expansion substantially similar to the coefficient of thermal expansion of the substrate processing chamber component.

11. A substrate processing chamber, comprising:
a processing volume defined by a top chamber wall, a bottom chamber wall and a plurality of side walls; and
a substrate processing chamber component disposed within the processing volume, wherein the substrate processing chamber component comprises
a body having a first surface,
one or more heat exchangers disposed within the body below the first surface, and
one or more anisotropic layers, wherein a separate anisotropic layer is disposed between each of the one or more heat exchangers and the first surface.

12. The substrate processing chamber of claim 11, wherein the substrate processing chamber component is at least one of a showerhead, an electrostatic chuck or a chamber liner.

13. The substrate processing chamber of claim 11, wherein the one or more heat exchangers are heaters.

14. The substrate processing chamber of claim 11, further comprising a plurality of temperature zones across the first surface of the body, wherein a temperature across each temperature zone is substantially uniform.

15. The substrate processing chamber of claim 14, wherein a temperature gradient within each temperature zone is about 1 to about 2 degrees Celsius.

16. The substrate processing chamber of claim 14, wherein each temperature zone is associated with a separate heat exchanger disposed within the body below each temperature zone.

17. The substrate processing chamber of claim 11, wherein the one or more heat exchangers are cooling channels.

18. The substrate processing chamber of claim 11, wherein each of the one or more heat exchangers and corresponding anisotropic layers are separated by an insulating material embedded within the body.

19. The substrate processing chamber of claim 11, comprising one or more power sources coupled to each of the one or more heat exchangers.

20. The substrate processing chamber of claim 11, wherein the anisotropic layer comprises a coefficient of thermal expansion substantially similar to the coefficient of thermal expansion of the substrate processing chamber component.
